(19) United States
(12) Patent Application Publication
(10) Pub. No.: US 2011/0298006 A1
(43) Pub. Date: Dec. 8, 2011

(54) SEMICONDUCTOR LIGHT EMITTING DEVICE AND METHOD FOR FABRICATING THE SAME

(75) Inventors: Hiroyuki HAGINO, Osaka (JP); Hiroshi OHNO, Osaka (JP); Kazuhiko YAMANAKA, Osaka (JP); Nobuaki NAGAO, Gifu (JP); Takahiro HAMADA, Osaka (JP)

(73) Assignee: PANASONIC CORPORATION, Osaka (JP)

(21) Appl. No.: 13/161,256

(22) Filed: Jun. 15, 2011

Related U.S. Application Data
(63) Continuation of application No. PCT/JP2010/006856, filed on Nov. 24, 2010.

(30) Foreign Application Priority Data
Jun. 2, 2010 (JP) 2010-126683

(51) Int. Cl. H01L 33/32; H01S 5/22; H01L 33/20

(52) U.S. Cl. 257/103; 438/39; 372/46.012; 257/E33.054; 257/E33.025; 257/E33.006

(57) ABSTRACT

A semiconductor light emitting device includes a nitride semiconductor layer including a first cladding layer, an active layer, and a second cladding layer, and a current blocking layer configured to selectively inject a current into the active layer. The second cladding layer has a stripe-shaped ridge portion. The current blocking layer is formed in regions on both sides of the ridge portion, and is made of zinc oxide having a crystalline structure.

### CROSS-REFERENCE TO RELATED APPLICATIONS

This is a continuation of PCT International Application PCT/JP2010/006856 filed on Nov. 24, 2010, which claims priority to Japanese Patent Application No. 2010-126683 filed on Jun. 2, 2010. The disclosures of these applications including the specifications, the drawings, and the claims are hereby incorporated by reference in their entirety.

### BACKGROUND

The present disclosure relates to semiconductor light emitting devices and methods for fabricating the devices, and more particularly, to semiconductor light emitting devices made of nitride semiconductors and methods for fabricating the devices.

Semiconductor light emitting devices made of nitride semiconductors composed of the group III element aluminum (Al), indium (In), and gallium (Ga) and the group V element nitrogen (N), have excellent features, such as small size, low cost, and high output power. Therefore, the semiconductor light emitting devices are used not only in the field of recording information onto optical disks etc. at high density, but also in a wide range of technical fields including image display, medicine, illumination, etc. For example, in the field of image display apparatuses, such as portable projectors etc., light emitting devices which emit light with high directivity, such as semiconductor laser devices, superluminescent diodes (SLDs), etc., have received attention as light sources. Image display devices require, as a light source, a pure-blue light emitting device having an emission wavelength of 430-480 nm and a pure-green light emitting device having an emission wavelength of 480-550 nm. Therefore, the semiconductor light emitting devices which can emit light having these wavelengths have been the subject of intense research and development. As light sources for high-density optical disks, blue-violet semiconductor laser devices having an emission wavelength of 400-410 nm are used. To improve the characteristics of the blue-violet semiconductor laser device is another important subject of development.

Light emitting devices made of nitride semiconductors typically have an optical waveguide in order to emit light having high directivity. The nitride semiconductor light emitting devices are also required to provide high output power with low power consumption, and therefore, the waveguide has a ridge structure. By forming an insulating film on both sides of the ridge, current injected from a p electrode provided on the top portion of the ridge can be confined, thereby efficiently confining carriers and light.

The nitride semiconductor light emitting device is required to have the following three characteristics. One is that the stability of the transverse mode needs to be improved. In order to stabilize the performance of optical disk reproduction and recording apparatuses or image display apparatuses, it is necessary to provide a uniform angle of divergence of light emitted from the light emitting device for each apparatus. To achieve this, it is necessary to stably control the width of the ridge in a wafer plane on a wafer on which the light emitting device is fabricated.

A second one is that the maximum light output and the efficiency of electricity-to-light conversion need to be improved. In optical disk reproduction and recording apparatuses, the light emitting device is required to provide higher output power in order to increase the recording speed. Also in image display apparatuses, the light emitting device (light source) is required to provide higher output power in order to achieve a higher-luminance and larger-size screen. Moreover, in order to reduce the power consumption of the apparatus during high light output operation, the light emitting device is required to have an improved efficiency of electricity-to-light conversion during the high light output operation.

A third one is that noise occurring due to light emitted by the light emitting device needs to be reduced. For example, in an optical system including the semiconductor laser device which is incorporated in an optical disk reproduction and recording apparatus, the light output of the semiconductor laser device becomes unstable due to optical feedback induced noise. The optical feedback induced noise refers to noise which is caused by light reflected from optical components returning to the semiconductor laser device. Also, in image display apparatuses, speckle noise, which is a flicker on the screen, occurs due to the coherence of light when the semiconductor laser device is used as the light source. In order to reduce speckle noise, the coherence of emitted light of the light emitting device needs to be reduced.

A fabrication process employing a technique called “resist etch back” has been proposed in order to improve the stability of the transverse mode (see, for example, Japanese Patent Publication No. 2005-347630). It is expected that the resist etch back technique can be used to form a p electrode which accurately matches the shape of the top portion of the ridge without need for precise alignment.

A structure in which an aluminum oxynitride (AlOₓN_{y}) film is formed on both sides of the ridge has been proposed in order to improve the maximum light output and the electricity-to-light conversion efficiency (see, for example, Japanese Patent No. 3982521). The aluminum oxynitride film, which has a higher thermal conductivity than those of silicon oxide (SiO₂) and aluminum oxide (Al₂O₃), is formed by sputtering. As a result, it is expected that thermal saturation is reduced during the high output power operation, whereby the maximum light output and the electricity-to-light conversion efficiency can be improved.

A self-pulsating light emitting device has been proposed in order to reduce noise (see, for example, Mitajima et al., “Generation of picosecond optical pulsed with a 2.4 W optical peak power from self-pulsating GaN-based bi-sectional laser diodes,” “The 8th International conference on Nitride Semiconductors,” Abstract Book, Volume 1, p. 33-34). A contact layer is formed in two separate regions on the top portion of the ridge, to provide a p electrode for the light emitting device and a p electrode for reverse biasing in the respective regions. The region where the reverse biasing p electrode is formed functions as a saturable absorption region. By adjusting a reverse bias applied to the reverse biasing p electrode, the amount of light absorbed in the saturable absorption region can be controlled, whereby self-pulsating operation can be achieved. It is expected that, in the self-pulsating light emitting device, the coherence of emitted light can be reduced, resulting in a reduction in noise caused by the coherence.

However, there is the following problem with the technique of stabilizing the transverse mode by resist etch back. When a nitride semiconductor layer is formed on a wafer, the formation process needs to be performed at high temperature, so that the wafer may be warped. Therefore, there is a limit of the reduction in variations in the ridge width. On the other hand, resist etch back requires formation of a SiO₂ film on a cladding layer. Because there is a large difference in refractive index between the nitride semiconductor cladding layer and the SiO₂ film, the transverse mode becomes unstable if the ridge width fluctuates. In particular, when a hetero-substrate, such as low-cost sapphire etc., is used as the wafer, the wafer is significantly warped, so that the transverse mode is likely to become unstable.

The technique of improving the output power and the electricity-to-light conversion efficiency by forming an aluminum oxynitride film on both sides of the ridge, has a problem that heat dissipation is insufficient. The aluminum oxynitride film is typically formed by electron cyclotron resonance sputtering. The aluminum oxynitride film formed by electron cyclotron resonance sputtering has a c-axis orientation, but insufficient crystallinity. The present inventors evaluated characteristics of the aluminum oxynitride film formed by electron cyclotron resonance sputtering to find that the thermal conductivity is 1.0 W/m·K. Thus, even when the aluminum oxynitride film is used, then if the light output is increased, the heat dissipation becomes insufficient.

The self-pulsating light emitting device with reduced noise has a problem that the saturable absorption region needs to be driven separately from the laser region. Therefore, complicated interconnection and a driver circuit are required in order to drive the saturable absorption region, leading to an increase in cost.

### SUMMARY

The present disclosure describes implementations of a semiconductor light emitting device made of a nitride semiconductor which has a stable transverse mode and can be fabricated by a simpler process than conventional processes.

An example semiconductor light emitting device of the present disclosure includes a current blocking layer made of zinc oxide having a crystalline structure.

Specifically, the example semiconductor light emitting device includes a nitride semiconductor layer formed on a substrate and including a first cladding layer, an active layer, and a second cladding layer, and a current blocking layer configured to selectively inject a current into the active layer. The second cladding layer has a stripe-shaped ridge portion. The current blocking layer is formed in regions on both sides of the ridge portion, and is made of zinc oxide having a crystalline structure.

In the example semiconductor light emitting device of the present disclosure, the current blocking layer is formed in regions on both sides of the ridge portion, and is made of zinc oxide having a crystalline structure. Therefore, the difference in refractive index between the current blocking layer and the ridge portion can be reduced. Moreover, the zinc oxide having a crystalline structure can be easily uniformly formed in the wafer plane by liquid phase growth. Therefore, the transverse mode can be stabilized. Moreover, the zinc oxide having a crystalline structure also has a high thermal conductivity, and therefore, the heat dissipation performance can be improved.

In the example semiconductor light emitting device of the present disclosure, the current blocking layer may contact a side wall of the ridge portion. With such a structure, it is possible to reduce or prevent formation of an air layer or insertion of an electrode material between the current blocking layer and the side surface of the ridge portion, whereby the transverse mode can be further stabilized.

In the example semiconductor light emitting device of the present disclosure, the ridge portion may be wider at an upper end thereof than at a lower end thereof. With such a structure, the contact area between the p electrode and the ridge portion can be increased, whereby the contact resistance can be reduced. As a result, the operating voltage can be reduced to improve the electricity-to-light conversion efficiency.

In the example semiconductor light emitting device of the present disclosure, there may be a plurality of the ridge portions, and the current blocking layer may be provided in regions on both sides of each of the plurality of ridge portions. With such a structure, there are a plurality of optical waveguides, whereby the light output of emitted light of the semiconductor light emitting device can be increased. Moreover, heat generated by the plurality of optical waveguides can be efficiently dissipated, whereby the electricity-to-light conversion efficiency can be improved.

In the example semiconductor light emitting device of the present disclosure, the zinc oxide forming the current blocking layer may have a light absorption property with respect to a wavelength of light emitted by the active layer. With such a structure, the light distribution can be controlled. Moreover, the optical gain of higher-order modes can be reduced, whereby the stability of the transverse mode can be improved.

In the example semiconductor light emitting device of the present disclosure, the zinc oxide forming the current blocking layer may contain at least one of copper and boron. With such a structure, a light absorption property can be easily imparted to the current blocking layer.

The example semiconductor light emitting device of the present disclosure may perform self-pulsating.

The example semiconductor light emitting device of the present disclosure may be a semiconductor laser device or a superluminescent diode.

In the example semiconductor light emitting device of the present disclosure, the substrate may be a sapphire substrate.

In the example semiconductor light emitting device of the present disclosure, the zinc oxide may be formed by liquid phase growth.

An example semiconductor light emitting apparatus of the present disclosure may include the semiconductor light emitting device of the present disclosure, and a package including a heat sink. The semiconductor light emitting device may be mounted on the package with a surface thereof farther from the substrate facing a surface of the heat sink. With such a structure, the heat dissipation performance can be further improved.

An example method for fabricating a semiconductor light emitting device according to the present disclosure includes the steps of (a) successively forming, on a substrate, a first cladding layer, an active layer, and a second cladding layer each made of a nitride semiconductor, (b) forming a stripe-shaped ridge portion in the second cladding layer, and (c) selectively epitaxially growing zinc oxide on both sides of the ridge portion by liquid phase growth.

The example semiconductor light emitting device fabrication method of the present disclosure may further include the step of (d) after step (c), forming a first electrode on the ridge portion. Step (b) may include the steps of (b1) forming a stripe-shaped mask on the second cladding layer, and (b2) forming the ridge portion by selectively etching the second cladding layer using the mask.

In the example semiconductor light emitting device fabrication method of the present disclosure, step (b) may include the steps of (b1) forming a stripe-shaped first electrode on the second cladding layer, and (b2) forming the ridge portion by selectively etching the second cladding layer using the first electrode as a mask. With such a structure, the manufacturing cost can be further reduced.

According to the semiconductor light emitting device of the present disclosure and the method for fabricating the semiconductor light emitting device, a semiconductor light emitting device which is made of a nitride semiconductor and has a stable transverse mode can be fabricated by a process simpler than conventional processes.

### BRIEF DESCRIPTION OF THE DRAWINGS

FIG. 1 is a cross-sectional view showing a semiconductor light emitting device according to a first embodiment.

FIGS. 2A-2D are cross-sectional views showing a method for fabricating the semiconductor light emitting device of the first embodiment in the order in which the device is fabricated.

FIG. 3 is an electron micrograph showing a portion of a current blocking layer in the semiconductor light emitting device of the first embodiment.

FIGS. 4A-4C are cross-sectional views showing a method for fabricating the semiconductor light emitting device of the first embodiment in the order in which the device is fabricated.

FIG. 5A is a plan view showing an implementation of the semiconductor light emitting device of the first embodiment.

FIG. 5B is a side view showing the implementation of the semiconductor light emitting device of the first embodiment.

FIG. 6 is a graph showing the relationship between wavelengths and refractive indices in the current blocking layer.

FIG. 7 is a graph showing the relationship between wavelengths and absorption coefficients in the current blocking layer.

FIG. 8 is a table showing properties of zinc oxide formed by liquid phase growth.

FIG. 9 is a graph showing light confinement of a current blocking layer made of zinc oxide formed by liquid phase growth.

FIG. 10 is a cross-sectional view showing a sample which is used in the measurement of FIG. 9.

FIG. 11 is a cross-sectional view showing a semiconductor light emitting device according to a first variation of the first embodiment.

FIGS. 12A-12C are cross-sectional views showing a method for fabricating the semiconductor light emitting device of the first variation of the first embodiment in the order in which the device is fabricated.

FIGS. 13A-13C are cross-sectional views showing a method for fabricating a semiconductor light emitting device according to a second variation of the first embodiment in the order in which the device is fabricated.

FIG. 14 is a cross-sectional view showing a semiconductor light emitting device according to a second embodiment.

FIGS. 15A-15C are cross-sectional views showing a method for fabricating the semiconductor light emitting device of the second embodiment in the order in which the device is fabricated.

FIG. 16A is a plan view showing an implementation of the semiconductor light emitting device of the second embodiment.

FIG. 16B is a side view showing the implementation of the semiconductor light emitting device of the second embodiment.

FIG. 17 is a table showing the thermal conductivity of zinc oxide.

FIG. 18 is a cross-sectional view showing a semiconductor light emitting device according to a variation of the second embodiment.

FIG. 19 is a cross-sectional view showing a semiconductor light emitting device according to a third embodiment.

FIG. 20 is a table showing the concentrations of impurities contained in a current blocking layer of the semiconductor light emitting device of the third embodiment.

### DETAILED DESCRIPTION

### First Embodiment

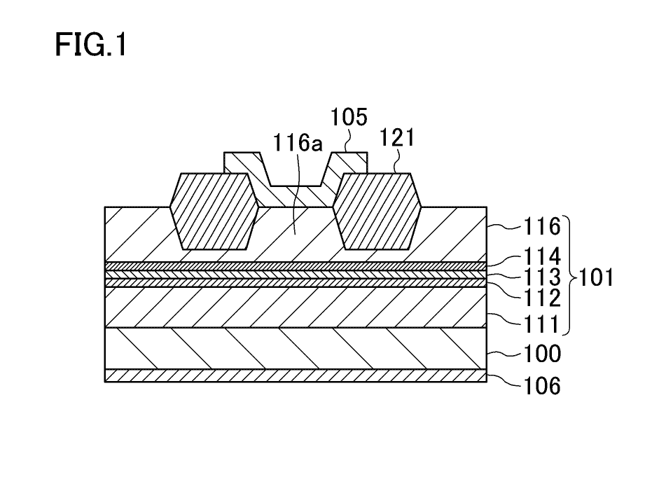

FIG. 1 shows a cross-sectional structure of a semiconductor light emitting device according to a first embodiment. As shown in FIG. 1, a nitride semiconductor layer 101 is formed on a substrate 100 made of n-type hexagonal GaN whose main surface is the (0001) plane. The nitride semiconductor layer 101 includes an n-type cladding layer 111, an n-type optical guide layer 112, a barrier layer (not shown), an active layer 113, a p-type optical guide layer 114, a carrier overflow suppression (OFS) layer (not shown), a p-type cladding layer 116, and a p-type contact layer (not shown), which are successively formed on the substrate 100. The n-type cladding layer 111 may be made of n-AlGaN, the n-type optical guide layer 112 may be made of n-GaN, and the barrier layer may be made of InGaN. The active layer 113 may be a quantum well active layer made of InGaN. The p-type optical guide layer 114 may be made of p-GaN, the OFS layer may be made of AlGaN, the p-type cladding layer 116 may be a strained superlattice layer made of p-AlGaN and GaN, and the p-type contact layer may be made of p-GaN.

The p-type cladding layer 116 has a stripe-shaped ridge portion 116a. A current blocking layer 121 made of zinc oxide having a crystalline structure is formed on both sides of the ridge portion 116a. Specifically, the current blocking layer 121 made of zinc oxide formed by liquid phase growth is buried in two recesses formed and spaced apart in the p-type cladding layer 116. A p electrode 105 is formed on the ridge portion 116a, extending over the current blocking layer 121 on both sides of the ridge portion 116a. An n electrode 106 is formed on the back surface of the substrate 100.

The current blocking layer 121 can confine a current injected from the p electrode 105 so that the current is selectively injected into a region of the active layer 113 below the ridge portion 116a. The ridge portion 116a and the region below the ridge portion 116a form an optical waveguide in which light emitted from the active layer 113 is confined. Light generated in the active layer 113 is confined in a direction (vertical direction) in which the layers are stacked, mainly by the difference in refractive index between the n-type optical guide layer 112 and the n-type cladding layer 111 and the difference in refractive index between the p-type optical guide layer 114 and the p-type cladding layer 116. The light is also confined in a direction perpendicular to the vertical direction and a direction in which the optical waveguide extends, mainly by an effective difference in refractive index between the ridge portion 116a and the current blocking layer 121. The light is guided through the optical waveguide. If a facet of the optical waveguide is formed to be perpendicular to the direction in the optical waveguide extends, a portion of the guided light is reflected back into the optical waveguide by the facet, so that light amplification (i.e., laser oscillation) occurs. On the other hand, if the light reflected by the optical waveguide facet is caused not to return to the optical waveguide, laser oscillation does not occur. In this case, therefore, a superluminescent diode is obtained which outputs light which results from induced amplification of spontaneous emission light. In order to cause the reflected light not to return to the optical waveguide, for example, the facet may be inclined at a predetermined angle relative to the direction in which the optical waveguide extends, or alternatively, a light absorber may be provided at the facet to absorb light. With such a structure, low coherence operation can be achieved, whereby speckle noise can be reduced.

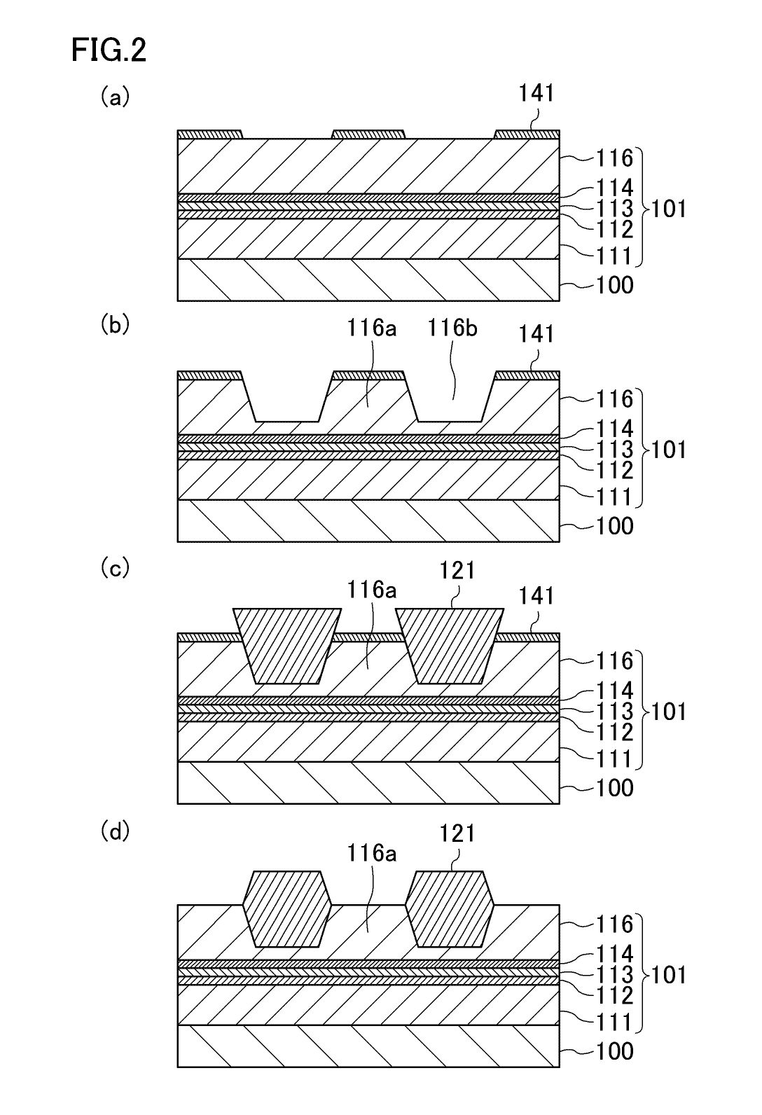

A method for fabricating the semiconductor light emitting device of this embodiment will be described hereinafter. Initially, as shown in FIG. 2A, for example, a nitride semiconductor layer 101 is grown on a substrate 100 made of n-type hexagonal GaN whose main surface is the (0001) plane, by metal organic chemical vapor deposition (MOCVD) etc. Next, a mask 141 is selectively formed on the nitride semiconductor layer 101.

For example, the nitride semiconductor layer 101 may include an n-type cladding layer 111, an n-type optical guide layer 112, an active layer 113 having a quantum well structure, a p-type optical guide layer 114, an OFS layer (not shown), a p-type cladding layer 116, and a contact layer (not shown), which are successively formed on the substrate 100. The n-type cladding layer 111 may be a 2 μm thick n-AlGaN layer. The n-type optical guide layer 112 may be a 0.1 μm thick n-GaN layer. The active layer 113 may include three periods of a barrier layer made of InGaN and a well layer made of InGaN. The p-type optical guide layer 114 may a 0.1 μm thick p-GaN layer. The OFS layer may be a 10 nm thick AlGaN layer. The p-type cladding layer 116 may be a strained superlattice layer including 160 periods of a 1.5 nm thick p-AlGaN layer and a 1.5 nm thick GaN layer, with a total thickness of 0.48 μm. The contact layer may be a 0.05 μm thick p-GaN layer.

The mask 141 may be formed by forming a 300 nm thick SiO₂ film on the nitride semiconductor layer 101 and then selectively removing the SiO₂ film. For example, initially, a SiO₂ film is formed on the nitride semiconductor layer 101 by thermal chemical vapor deposition (thermal CVD) using monosilane (SiH₄). Next, a photoresist layer having stripe-shaped openings having a width of 1.5 μm may be formed on the SiO₂ film by photolithography. Thereafter, the exposed portions of the SiO₂ film may be removed by reactive ion etching (ME) using carbon tetrafluoride (CF₄).

Next, as shown in FIG. 2B, the p-type cladding layer 116 is selectively removed using the mask 141 to form stripe-shaped recesses 116b having a depth of about 400 nm. As a result, the stripe-shaped ridge portion 116a is formed in the p-type cladding layer 116. The p-type cladding layer 116 may be removed by inductively coupled plasma (ICP) etching using chlorine (Cl₂).

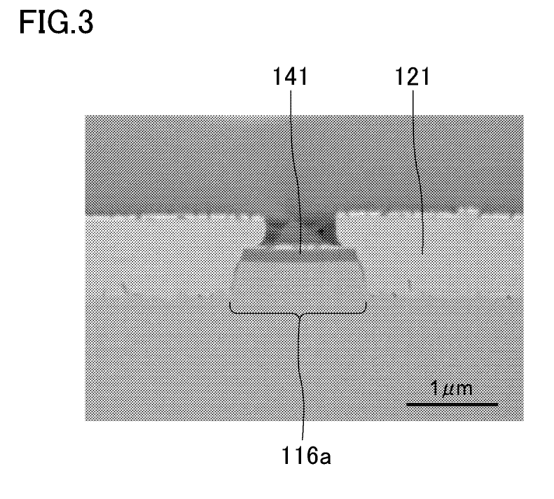

Next, as shown in FIG. 2C, the current blocking layer 121 made of ZnO is epitaxially grown in the recess 116b by liquid phase growth. For example, the growth of ZnO is achieved by immersing the substrate 100 on which the nitride semiconductor layer 101 has been formed, in a solution containing zinc nitrate hexahydrate and hexamethylene tetramine at a temperature of 70° C. for 5 hours. As shown in FIG. 3, ZnO is not grown on the mask 141 made of SiO₂, and is selectively grown only on the exposed p-type cladding layer 116. Even when the wafer is warped, ZnO can be uniformly grown in the wafer plane, whereby the yield can be increased. The ZnO grown by this method has n-type conductivity. Therefore, pn junction is formed at an interface between the ZnO layer and the p-type cladding layer 116. The reverse biasing effect of the pn junction can provide a current confinement function.

Next, as shown in FIG. 2D, the mask 141 is removed by wet etching using, for example, a hydrofluoric acid solution having a concentration of about 5%.

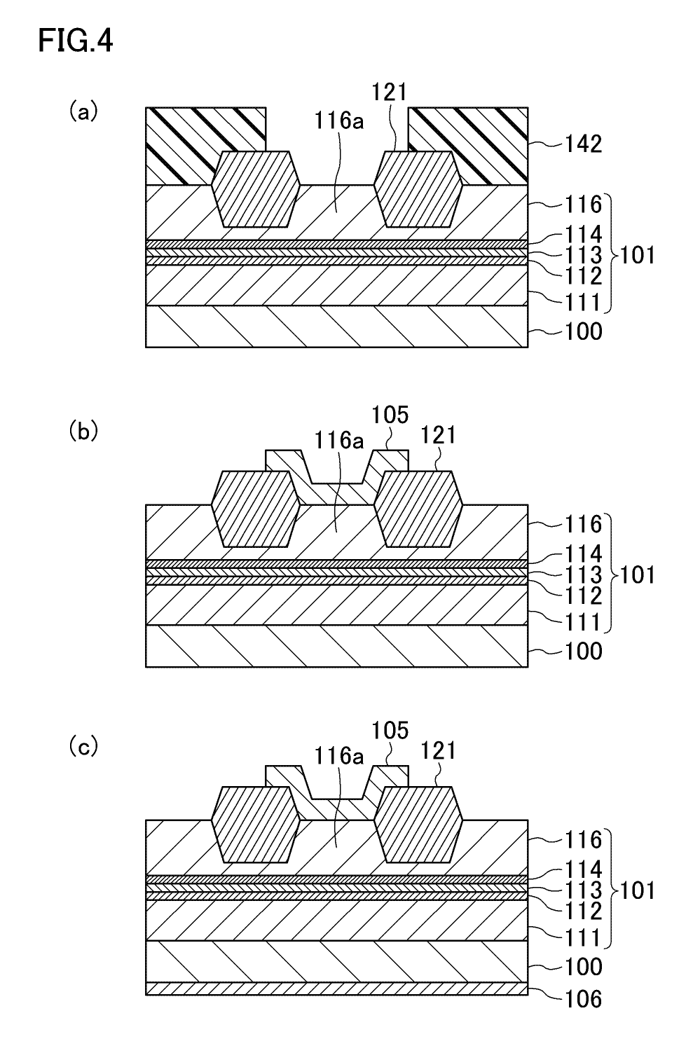

Next, as shown in FIG. 4A, a resist mask 142 having a stripe-shaped opening about 2 μm wide in which the ridge portion 116a is exposed is formed by photolithography.

Next, as shown in FIG. 4B, the p electrode 105 is formed. For example, a 50 nm thick palladium (Pd) layer and a 50 nm thick platinum (Pt) layer are successively formed on an entire surface of the substrate 100 by electron beam (EB) deposition. Next, the Pd and Pt layers are removed by lift-off, excluding the Pd and Pt layers on the ridge portion 116a, to form the p electrode 105. Thereafter, sintering is performed at a temperature of about 400° C. to form ohmic contact. Next, an interconnect electrode (not shown) is formed to cover the ridge portion 116a. The interconnect electrode is about 500 μm long in the stripe direction and about 150 μm wide in a direction perpendicular to the stripe direction. For example, the interconnect electrode may be made of a multilayer film including a 50 nm thick titanium (Ti) layer, a 50 nm Pt layer, and a 100 nm gold (Au) layer, and may be formed by photolithography and etching.

Next, as shown in FIG. 4C, the back surface of the substrate 100 is polished to a thickness of about 80 μm using a diamond slurry before the n electrode 106 is formed on the back surface of the substrate 100. For example, the n electrode 106 may be made of a multilayer film including a 5 nm thick Ti layer, a 50 nm Pt layer, and a 100 nm Au layer, and may be formed by EB deposition. The wafer may be cleaved into individual semiconductor light emitting devices having, for example, an optical cavity width of 200 μm and an optical cavity length of 800 μm.

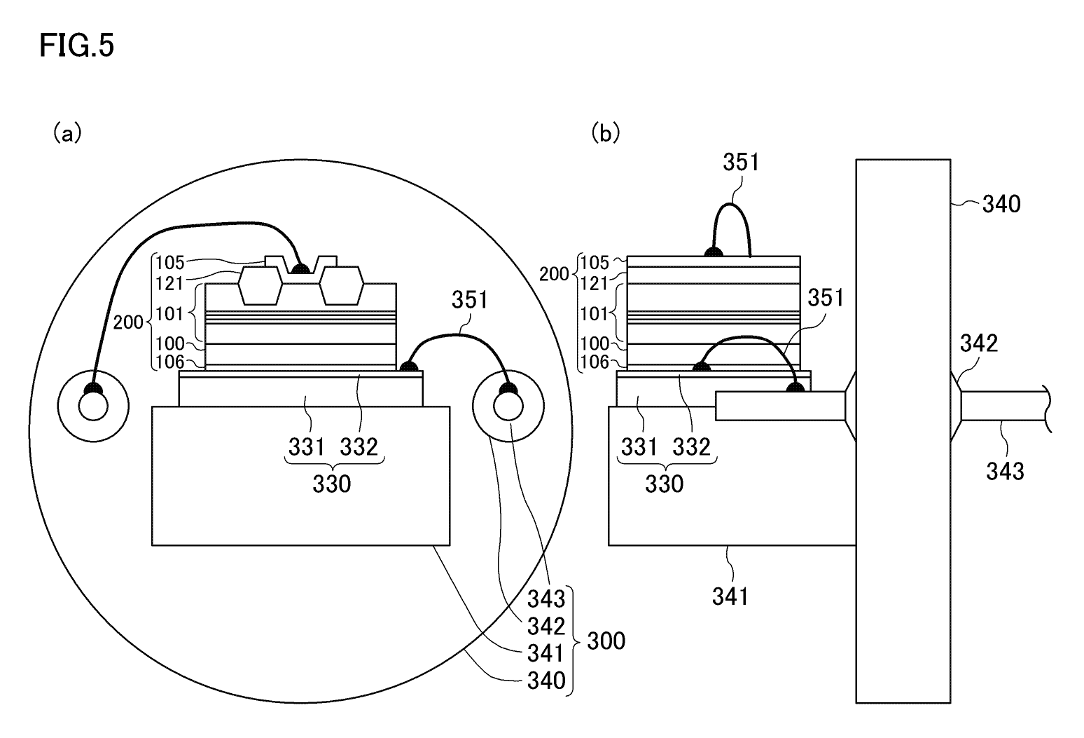

FIG. 5A shows a structure of an example implementation of the semiconductor light emitting device of this embodiment as viewed from a light emitting face. FIG. 5B shows a structure of the example semiconductor light emitting device as viewed from a side face. As shown in FIGS. 5A and 5B, the semiconductor light emitting device 200 is mounted on a package 300. The package 300 includes a base 340 made of iron etc., a heat sink 341 made of copper etc. and attached to the base 340, and leads 343 attached to the base 340 via insulators 342. The semiconductor light emitting device 200 is attached to the heat sink 341 via a submount 330 made of AlN ceramic etc. The submount 330 includes a submount baseboard 331 and a submount electrode 332 formed on a surface of the submount baseboard 331. The n electrode 106 of the semiconductor light emitting device 200 is connected to the submount electrode 332. Heat generated in the semiconductor light emitting device 200 is transferred via the submount 330 to the heat sink 341. The heat transferred to the heat sink 341 is dissipated from the heat sink 341, and a portion of the heat is transferred to and then dissipated from the base 340. The submount electrode 332 is connected via a wire 351 to one of the leads 343. The other lead 343 is connected via another wire 351 to the p electrode 105.

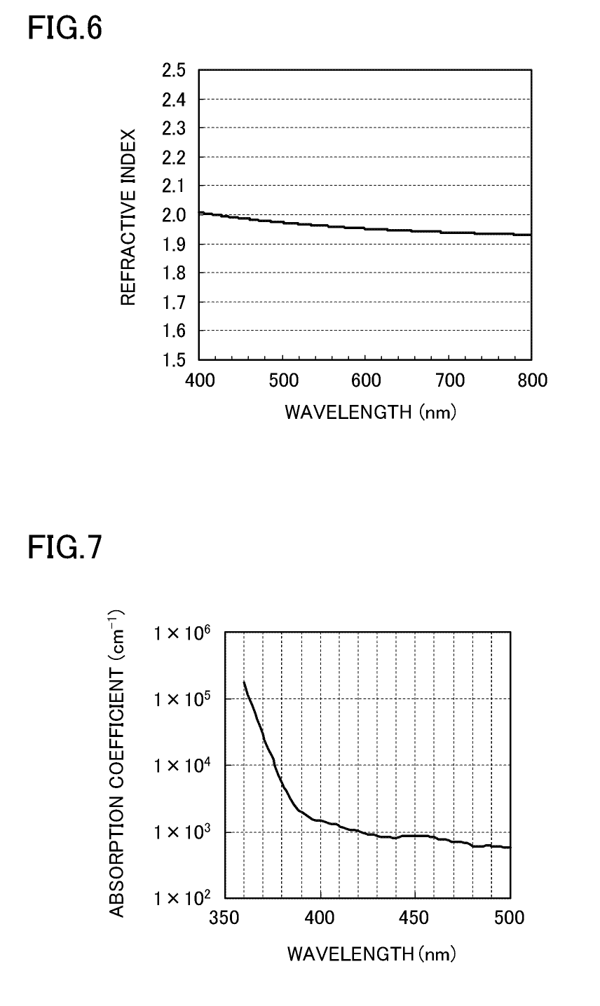

FIG. 6 shows the refractive index of ZnO epitaxially grown by liquid phase growth. The refractive index is from about 2.0 to about 1.9 within the wavelength range of 400-800 nm. For example, when the wavelength is 405 nm, the refractive index is 2.0. When the wavelength is 405 nm, the refractive index of SiO₂ is about 1.5. Thus, the refractive index of the ZnO is greater than that of SiO₂ when the wavelength is 405 nm.

FIG. 7 shows the absorption coefficient of a ZnO layer. The absorption coefficient is about 1×10³ cm⁻¹ when the wavelength is within the range of about 400-500 nm. For example, when the wavelength is 405 nm, the absorption coefficient is 1.34×10³ cm⁻¹.

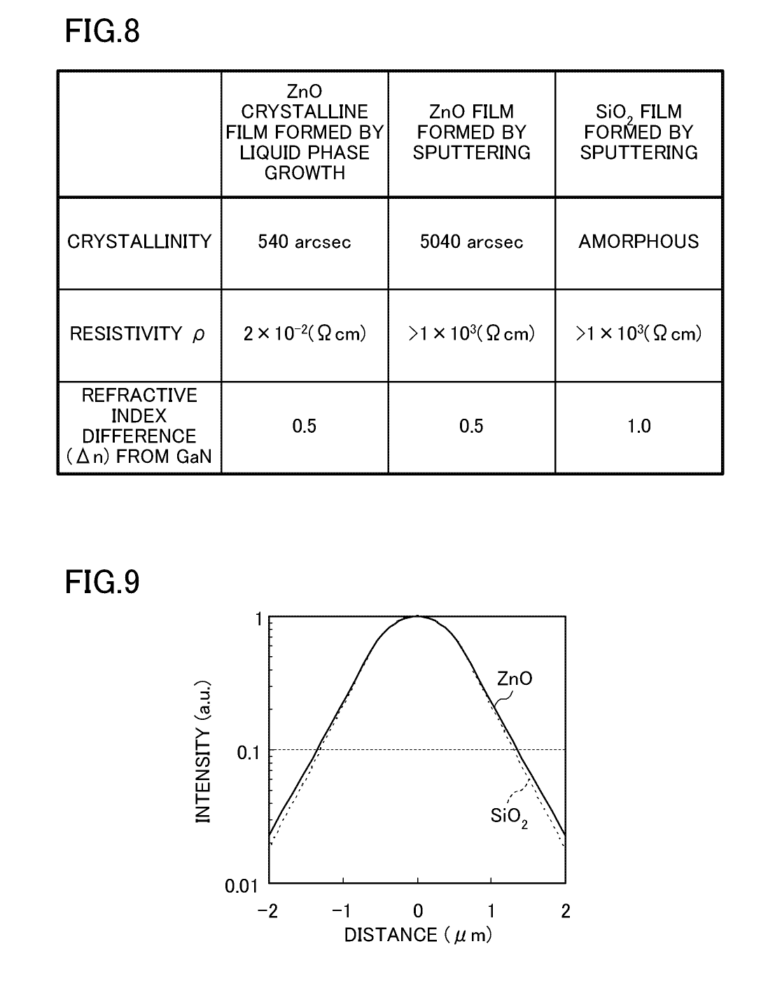

FIG. 8 shows physical properties of ZnO epitaxially grown by liquid phase growth. The ZnO epitaxially grown by liquid phase growth has a full width at half maximum of 540 arcsec as measured by X-ray diffraction (XRD). On the other hand, ZnO formed by sputtering has a full width at half maximum of 5040 arcsec. The resistivity p of the ZnO formed by liquid crystal growth is 2×10⁻² Ωcm, while the resistivity p of the ZnO formed by sputtering is 1×10³ Ωcm. Therefore, it is clear that the liquid phase growth technique can form ZnO having a crystalline structure with more excellent crystallinity than that which is obtained by the sputtering technique. The difference Δn in refractive index between ZnO and GaN when the wavelength is 405 nm is about 0.5, which is smaller than that between ZnO and amorphous SiO₂, which is typically used. Therefore, the transverse mode can be stabilized.

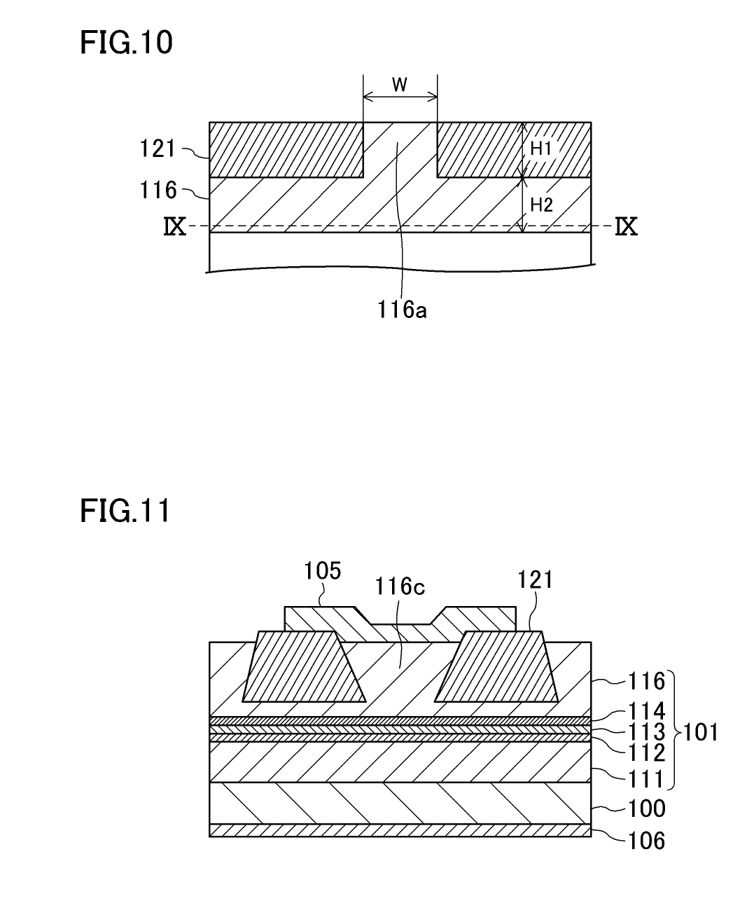

FIG. 9 shows a comparison between light confinement where the current blocking layer is made of the ZnO formed by liquid crystal growth and light confinement where the current blocking layer is made of SiO₂. The result of FIG. 9 is measured using a structure shown in FIG. 10. The ridge portion 116a has a width (w) of 1.3 μm. The p-type cladding layer other than the ridge portion 116a has a height (H1) of 200 nm. The ridge portion 116a has a height from bottom to top (H2) of 200 nm. In FIG. 9, the vertical axis indicates intensities of electric field in the resonance mode along line IX-IX of FIG. 10, and the horizontal axis indicates positions where the center of the ridge portion 116a is zero. As shown in FIG. 9, by using, as the current blocking layer, the ZnO having a crystalline structure formed by liquid crystal growth, the light distribution can be wider than that which is obtained when the SiO₂ layer is used.

The width of the current blocking layer 121 in a direction perpendicular to the ridge portion 116a may be arbitrarily set. The current blocking layer 121 may be extended to a side surface of the nitride semiconductor layer 101.

(First Variation of First Embodiment)

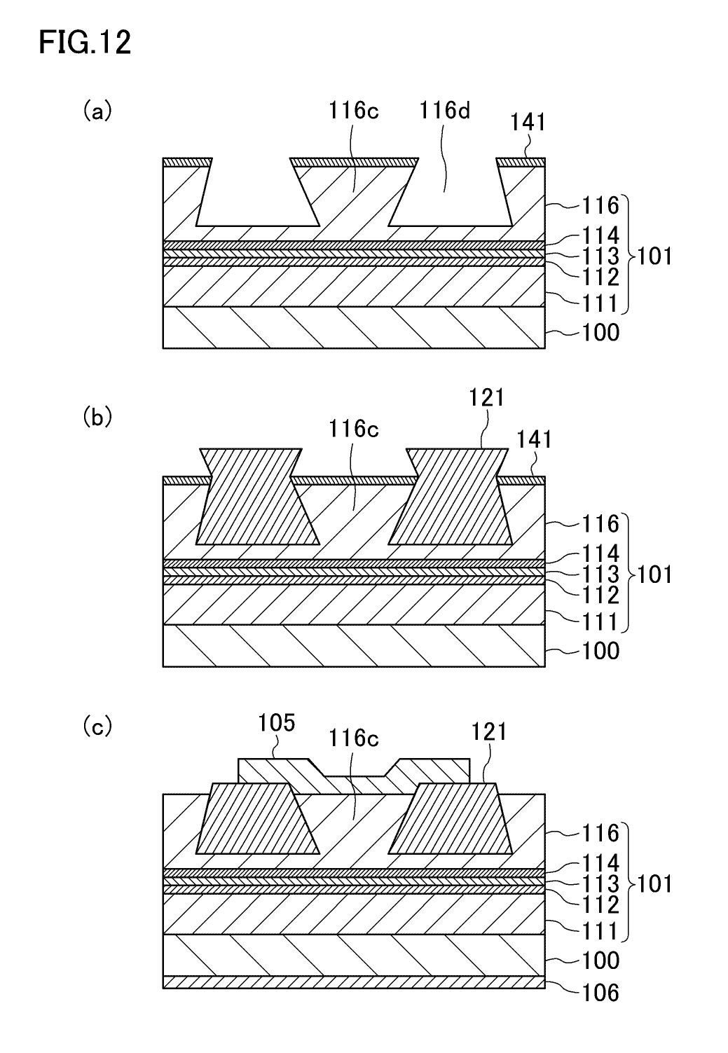

In the first embodiment, the ridge portion is forwardly tapered, i.e., the width of the upper portion is smaller than the width of the lower portion. As shown in FIG. 11, however, a reversely tapered ridge portion 116c may be employed, i.e., the width of the upper portion may be greater than the width of the lower portion. In this case, as shown in FIG. 12A, the p-type cladding layer 116 may be etched so that the width of the lower portion becomes smaller than the width of the upper portion, to form stripe-shaped recesses 116d which become wider toward the lower end. Thereafter, as shown in FIG. 12B, a current blocking layer 121 made of ZnO may be formed by liquid phase growth using a process similar to that described above. Next, as shown in FIG. 12C, a p electrode 105 and an n electrode 106 may be formed. As a result, a semiconductor light emitting device having the reversely tapered ridge portion 116c can be provided.

The ridge portion is typically forwardly tapered so that the side walls of the ridge portion can be easily covered with an insulating film. In this case, the area of the top portion of the ridge is small, so that the contact resistance increases, and therefore, the operating voltage is likely to increase. However, in the case of the reversely tapered ridge portion 116c, the contact area between the p electrode 105 and the ridge portion 116c at the top portion of the ridge can be increased, whereby the contact resistance can be reduced. As a result, the operating voltage can be reduced, whereby the electricity-to-light conversion efficiency can be improved.

(Second Variation of First Embodiment)

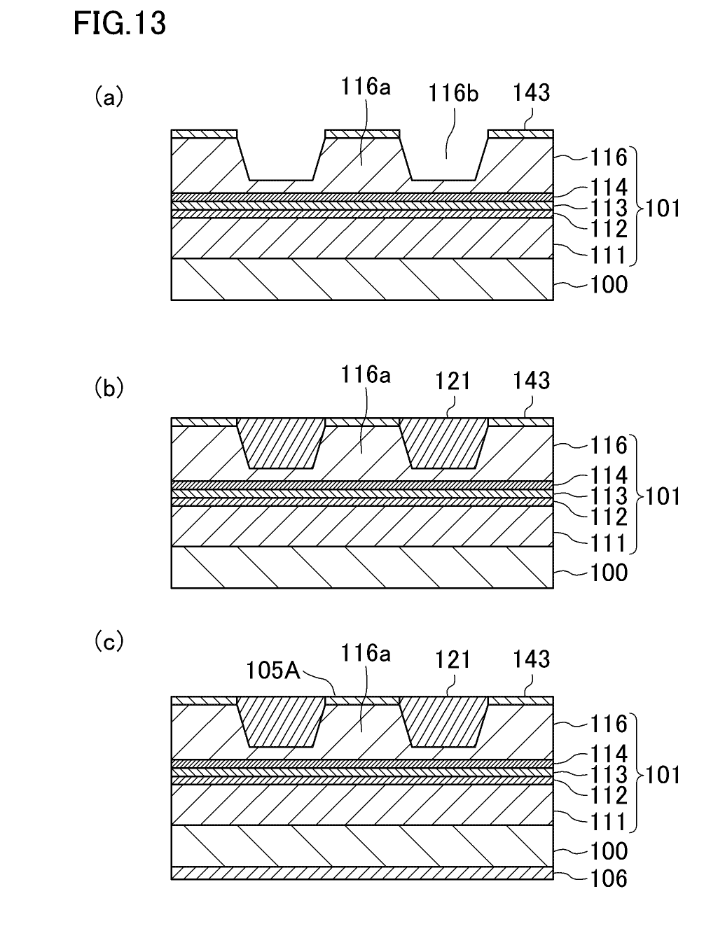

An example has been described above in which a SiO₂ film is used as an etching mask for forming the ridge portion and a growth mask for selectively growing the current blocking layer. Instead of the SiO₂ film, a metal film which is the same as that of which the p electrode is made may be used. In this case, as shown in FIG. 13A, the ridge portion 116a is formed using a metal film 143 as an etching mask. Next, as shown in FIG. 13B, the current blocking layer 121 is epitaxially grown using the metal film 143 as a growth mask. Thereafter, as shown in FIG. 13C, the n electrode 106 is formed on the back surface of the substrate 100, and a portion of the metal film 143 formed on the ridge portion 116a is a p electrode 105A. Thus, the fabrication process can be further simplified.

### Second Embodiment

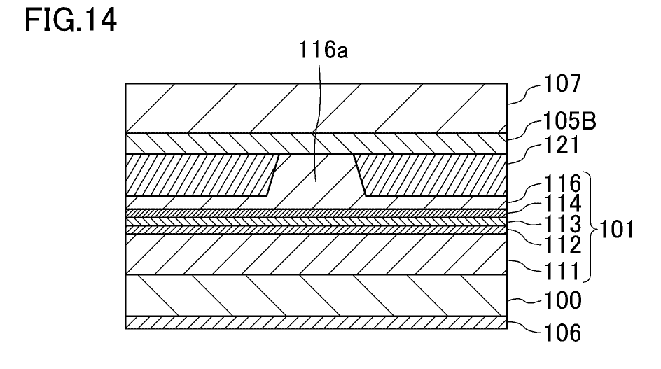

FIG. 14 shows a cross-sectional structure of a semiconductor light emitting device according to a second embodiment. In FIG. 14, the same parts as those of FIG. 1 are indicated by the same reference characters. As shown in FIG. 14, the semiconductor light emitting device of the second embodiment has a feature that the height of a current blocking layer 121 made of ZnO having a crystalline structure is substantially the same as the height of a ridge portion 116a. Also, a p electrode 105B which is substantially flat is formed, extending over the current blocking layer 121 and the ridge portion 116a. With such a structure, the heat dissipation performance of the semiconductor light emitting device can be improved.

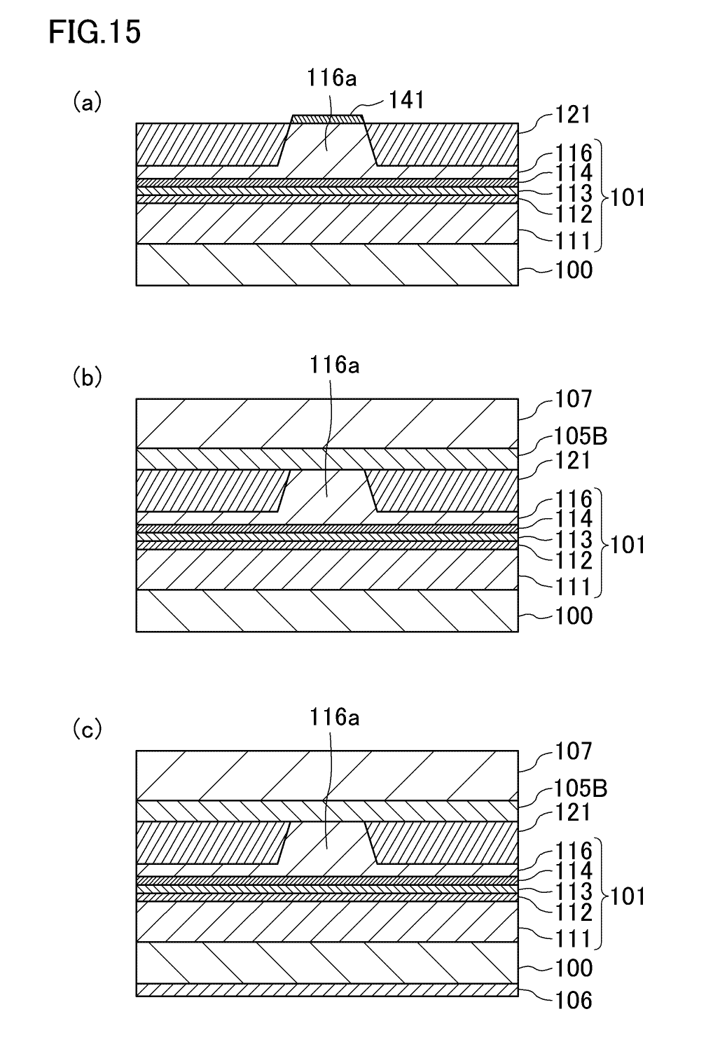

The semiconductor light emitting device of this embodiment is fabricated in a manner similar to that of the first embodiment until the ridge portion 116a is formed. Thereafter, as shown in FIG. 15A, the current blocking layer 121 made of ZnO is formed to a thickness of about 400 nm so that the upper surface of the current blocking layer 121 and the upper surface of the ridge portion 116a have substantially the same height. Next, after the mask 141 made of SiO₂ is removed, as shown in FIG. 15B a p electrode 105B is formed by EB deposition etc. to cover the current blocking layer 121 and the ridge portion 116a. Moreover, an interconnect electrode 107 is formed which is about 500 μm long in a direction in which the ridge portion 116a extends, and about 150 μm wide in a direction perpendicular to the ridge portion 116a. The interconnect electrode 107 may be, for example, a multilayer film including a 50 nm thick Ti layer, a 50 nm thick Pt layer, and a 100 nm thick Au layer. Next, as shown in FIG. 15C, after the substrate 100 is polished, an n electrode 106 is formed on the back surface of the substrate 100. The wafer may be cleaved into individual semiconductor light emitting devices having, for example, an optical cavity width of 200 μm and an optical cavity length of 800 μm.

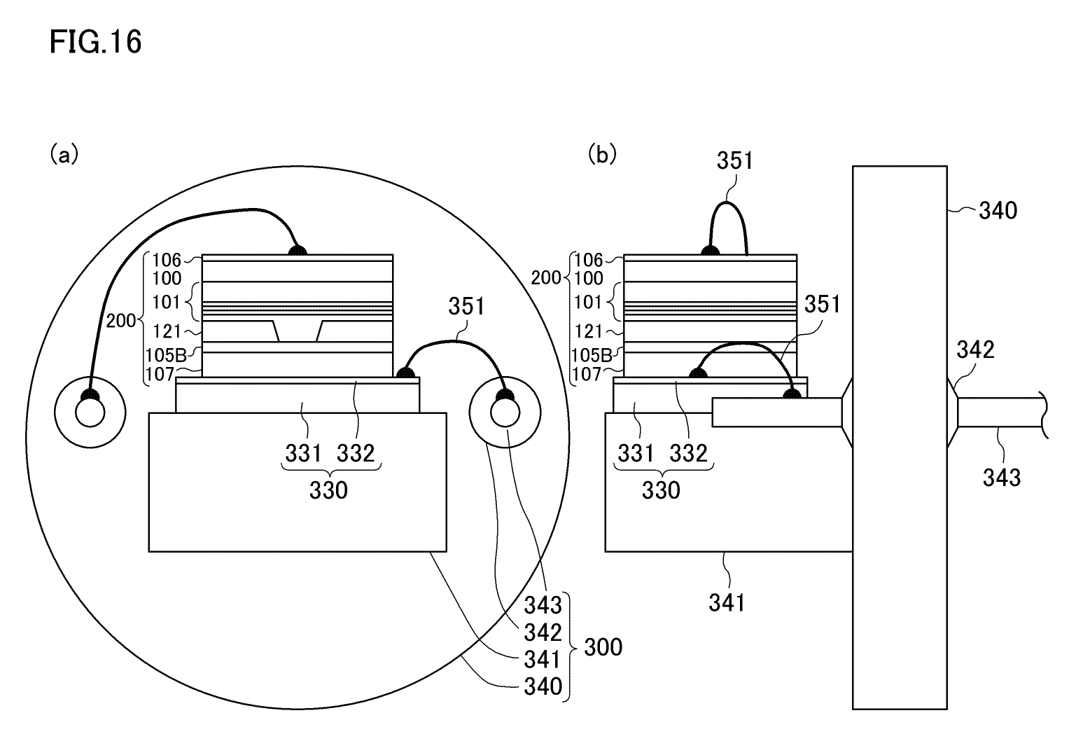

FIG. 16A shows a structure of an example implementation of the semiconductor light emitting device of this embodiment as viewed from a light emitting face. FIG. 16B shows a structure of the example semiconductor light emitting device as viewed from a side face. As shown in FIGS. 16A and 16B, an interconnect electrode 107 of the semiconductor light emitting device 200 of this embodiment is connected to a submount electrode 332. Therefore, heat generated in the nitride semiconductor layer 101 can be efficiently dissipated. Note that, as in the first embodiment, the n electrode 106 may also be connected to the submount electrode 332.

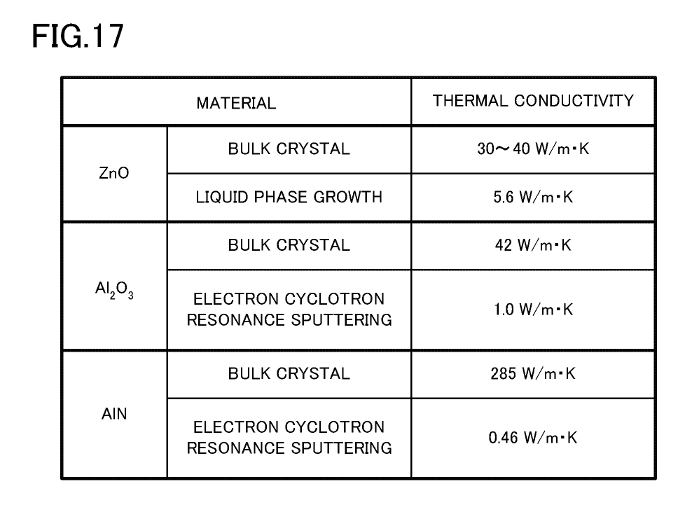

FIG. 17 shows the thermal conductivities of various materials. The thermal conductivities of aluminum oxide (Al₂O₃) and aluminum nitride (AlN) are higher than that of ZnO when they are a bulk crystal. However, Al₂O₃ and AlN which are formed by electron cyclotron resonance sputtering have a thermal conductivity of as low as 1.0 W/m·K and 0.46 W/m·K, respectively. On the other hand, ZnO which is formed by liquid phase growth has a thermal conductivity of as high as 5.6 W/m·K. Therefore, it is clear that the semiconductor light emitting device of this embodiment has high heat dissipation performance.

Note that, even in the structures of the first and second variations of the first embodiment, a semiconductor light emitting device having a flat p electrode can be provided by adjusting the thickness of the current blocking layer. Also, the width of the current blocking layer 121 in a direction perpendicular to the ridge portion 116a may be arbitrarily set. The current blocking layer 121 may not be extended to a side surface of the nitride semiconductor layer 101.

(Variation of Second Embodiment)

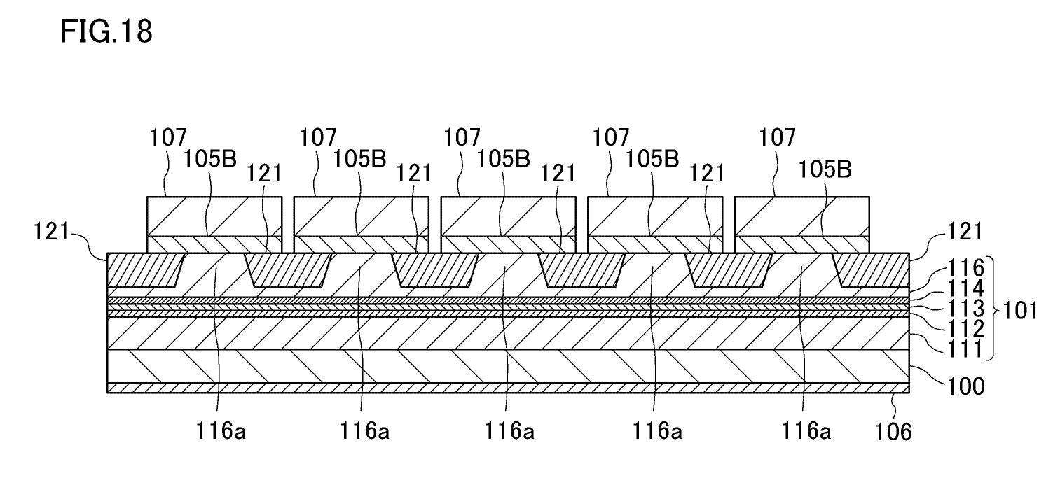

If the current blocking layer 121 is made of ZnO having a crystalline structure, heat can be efficiently dissipated. Therefore, as shown in FIG. 18, a plurality of the ridge portions 116a may be formed, whereby the maximum light output of emitted light can be easily increased.

In FIG. 18, power can be supplied to the individual ridge portions 116a separately, whereby the light outputs of the ridge portions 116a can be separately adjusted. In order to supply power separately, the submount electrode may be patterned to form a plurality of interconnect electrodes, and the p electrodes 105B may be connected to the respective interconnect electrodes. In the package, leads may be provided, of which there are the same number as there are the ridge portions 116a, and the interconnect electrodes may be connected to the respective leads via respective wires. When the n electrode 106 is connected to the submount electrode, the p electrodes 105B may be connected to the respective leads via respective wires.

Note that the ridge portions may share a common p electrode. In this case, heat generated in the ridge portions is diffused in the nitride semiconductor light emitting device via the current blocking layer, resulting in a uniform temperature distribution. Therefore, by forming the current blocking layer of ZnO having a crystalline structure, variations in the serial resistance of the ridge portions can be reduced, whereby the intensities of light emitted from the ridge portions can be caused to be substantially the same.

### Third Embodiment

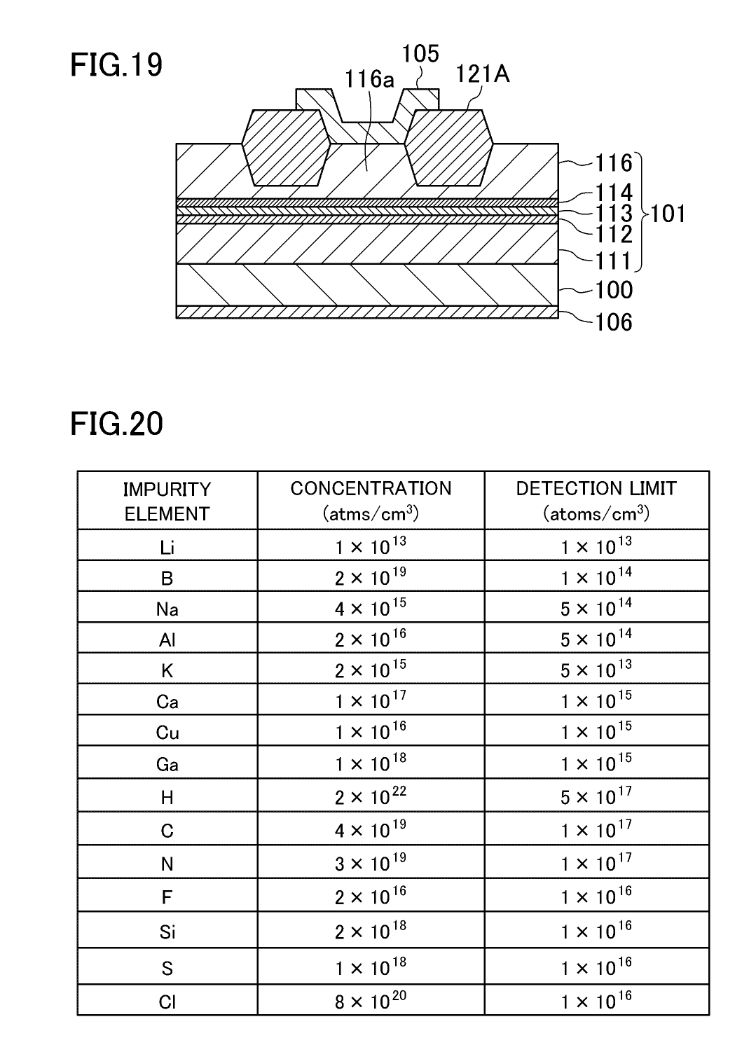

A semiconductor light emitting device according to a third embodiment is of the self-pulsation type. The self-pulsating semiconductor light emitting device can reduce noise. In the self-pulsating semiconductor light emitting device, as shown in FIG. 19 a current blocking layer 121A made of ZnO having a different optical characteristic may be formed.

The current blocking layer 121A may be, for example, made of ZnO which is epitaxially grown by liquid phase growth using a solution containing an impurity ion, such as Cu, B, etc. By using the ZnO containing an impurity, such as Cu, B, etc., a portion of light emitted by an active layer 113 can be absorbed by the current blocking layer 121A.

A saturable absorption region can be formed by controlling a current injection region and a light distribution region. The saturable absorption region refers to a region in which the carrier concentration increases due to light absorption, but the amount of absorbed light decreases with an increase in light and is finally saturated. By forming the saturable absorption region, self-pulsation can be achieved.

When a current is injected via the electrode into the active layer 113, carriers are accumulated in the active layer 113, so that the gain of the active layer 113 increases. However, in the saturable absorption region provided adjacent to the current injection region, carriers absorb light, i.e., there is a loss. If the carrier concentration increases, so that the total gain of the current injection region and the saturable absorption region exceeds the threshold gain, laser oscillation occurs. At the same time, the carrier concentration rapidly decreases. In this case, edge portions of the light distribution caused by the laser oscillation are absorbed in the saturable absorption region, and therefore, the carrier concentration increases in the saturable absorption region, but the absorption amount is eventually saturated. In this case, the total number of carriers in the current injection region and the saturable absorption region decreases, and if no carrier exists, the oscillation stops. The repetition of this operation is self-pulsation.

The light distribution is controlled by adjusting the thickness of the p-type cladding layer remaining around the ridge portion, or providing an absorber which absorbs generated light. The latter technique has higher controllability. In this embodiment, by using the current blocking layer 121A made of ZnO doped with boron having a concentration of 2×10¹⁹ atoms/cm³, the light distribution is controlled to achieve self-pulsation.

The current blocking layer 121A made of boron-doped ZnO having a crystalline structure may be, for example, formed by adding 0.02 M dimethylamine borane as a boron source to a solution which is used to expitaxialy grow ZnO. FIG. 20 shows example concentrations of elements contained in the current blocking layer which are measured by secondary ion mass scattering spectroscopy (SIMS). As shown in FIG. 20, the concentration of boron contained in the current blocking layer is about 2×10¹⁹ atoms/cm³.

In this embodiment, the upper surface of the current blocking layer 121A and the upper surface of the ridge portion 116a may have substantially the same height. The reversely tapered the ridge portion 116c may also be used.

While, in the embodiments and the variations described above, the substrate is made of GaN, a sapphire substrate, a silicon carbide substrate, etc. may instead be used to reduce manufacturing cost. Because the semiconductor light emitting devices of the embodiments and the variations described above include a current blocking layer made of ZnO having a crystalline structure, even if a low-cost hetero-substrate is used, a stable transverse mode can be achieved.

According to the nitride semiconductor light emitting device of the present disclosure and the method for fabricating the nitride semiconductor light emitting device, a semiconductor light emitting device which is made of a nitride semiconductor and has a stable transverse mode can be fabricated by a process simpler than conventional processes. In particular, the present disclosure is useful for semiconductor light emitting devices made of nitride semiconductors, methods for fabricating the semiconductor light emitting devices, etc.

What is claimed is:

1. A semiconductor light emitting device comprising:
a nitride semiconductor layer formed on a substrate and including a first cladding layer, an active layer, and a second cladding layer; and
a current blocking layer configured to selectively inject a current into the active layer,
wherein
the second cladding layer has a stripe-shaped ridge portion, and
the current blocking layer is formed in regions on both sides of the ridge portion, and is made of zinc oxide having a crystalline structure.

2. The semiconductor light emitting device of claim 1, wherein
the current blocking layer contacts a side wall of the ridge portion.

3. The semiconductor light emitting device of claim 2, wherein
the ridge portion is wider at an upper end thereof than at a lower end thereof.

4. The semiconductor light emitting device of claim 1, wherein
there are a plurality of the ridge portions, and
the current blocking layer is formed in regions on both sides of each of the plurality of ridge portions.

5. The semiconductor light emitting device of claim 1, wherein
the zinc oxide has a light absorption property with respect to a wavelength of light emitted by the active layer.

6. The semiconductor light emitting device of claim 1, wherein
the zinc oxide contains at least one of copper and boron.

7. The semiconductor light emitting device of claim 1, wherein
the semiconductor light emitting device performs self-pulsation.

8. The semiconductor light emitting device of claim 1, wherein
the semiconductor light emitting device is a semiconductor laser device.

9. The semiconductor light emitting device of claim 1, wherein
the semiconductor light emitting device is a superluminescent diode.

10. The semiconductor light emitting device of claim 1, wherein
the substrate is a sapphire substrate.

11. The semiconductor light emitting device of claim 1, wherein
the zinc oxide is formed by liquid phase growth.

12. A semiconductor light emitting apparatus comprising:
the semiconductor light emitting device of claim 1; and
a package including a heat sink,
wherein
the semiconductor light emitting device is mounted on the package with a surface thereof farther from the substrate facing a surface of the heat sink.

13. A method for fabricating a semiconductor light emitting device comprising the steps of:
(a) successively forming, on a substrate, a first cladding layer, an active layer, and a second cladding layer each made of a nitride semiconductor;
(b) forming a stripe-shaped ridge portion in the second cladding layer; and
(c) selectively epitaxially growing zinc oxide on both sides of the ridge portion by liquid phase growth.

14. The method of claim 13, further comprising the step of:
(d) after step (c), forming a first electrode on the ridge portion,
wherein
step (b) includes the steps of
(b1) forming a stripe-shaped mask on the second cladding layer, and
(b2) forming the ridge portion by selectively etching the second cladding layer using the mask.

15. The method of claim 13, wherein
step (b) includes the steps of
(b1) forming a stripe-shaped first electrode on the second cladding layer, and
(b2) forming the ridge portion by selectively etching the second cladding layer using the first electrode as a mask.
